(19) United States
(12) Patent Application Publication
(10) Pub. No.: US 2010/0308449 A1
(43) Pub. Date: Dec. 9, 2010

(54) SEMICONDUCTOR PACKAGES AND MANUFACTURING METHOD THEREOF

(76) Inventors: Hung-Jen YANG, Kaohsiung City (TW); Min-Lung Huang, Kaohsiung City (TW)

Correspondence Address: COOLEY LLP;ATTN: Patent Group, Suite 1100, 777 - 6th Street, NW, WASHINGTON, DC, 20001, US

(21) Appl. No.: 12/612,304

(22) Filed: Nov. 4, 2009

(30) Foreign Application Priority Data
Jun. 3, 2009 (TW) 98118370

(51) Int. Cl. H01L 23/498; H01L 21/60

(52) U.S. Cl. 257/690; 438/113; 257/E23.069; 257/E21.508

(57) ABSTRACT

A manufacturing method of semiconductor package is provided. A carrier is provided. The chips are disposed on the carrier. The chips are encapsulated by a molding compound, so that the molding compound and the chips form a chip-redistribution encapsulant. The carrier is removed, so that the chip-redistribution encapsulant exposes the pads of the chips. The plasma is applied on the pads and the molding compound. A first dielectric layer is formed on the pads and the surface of the molding compound. The plasma is applied on a surface of the first dielectric layer. A patterned conductive layer is formed on the surface of the first dielectric layer. A second dielectric layer is formed on the patterned conductive layer and the first dielectric layer. A plurality of solder balls are formed on the second dielectric layer. The chip-redistribution encapsulant is divided so as to form a plurality of packages.

This application claims the benefit of Taiwan application Serial No. 98118370, filed Jun. 3, 2009, the subject matter of which is incorporated herein by reference.

### BACKGROUND

1. Technical Field

The disclosure relates in general to a semiconductor package and a manufacturing method thereof, and more particularly to a semiconductor package adopting plasma manufacturing process and a manufacturing method thereof.

2. Description of the Related Art

Referring to FIG. 1, a partial cross-sectional view of a generally known semiconductor package is shown. On the part of the semiconductor package 100, a first dielectric layer 104 is formed first, then a patterned conductive layer 102 is formed next, and a second dielectric layer 108 is formed afterwards.

However, during the process of forming the patterned conductive layer 102, there will be residual metal atoms left on the surface 106 of the first dielectric layer 104. After the patterned conductive layer 102 is formed, the second dielectric layer 108 directly formed on the first dielectric layer 104.

### SUMMARY

The disclosure is directed to a method of manufacturing a semiconductor package. Before the first dielectric layer is formed, plasma surface treatment is applied on the molding compound surface for removing impurities from the surface of the molding compound and making the molding compound surface a rough structure so as to increase the associativity between the first dielectric layer being formed subsequently and the molding compound surface. Besides, after the first dielectric layer is formed, plasma surface treatment is applied on the surface of the first dielectric layer for removing impurities from the surface of the first dielectric layer and making the surface of the first dielectric layer a rough structure so as to increase the associativity between the patterned conductive layer being formed subsequently and the surface of the first dielectric layer.

According to a first aspect of the disclosure, a method of manufacturing a semiconductor package is provided. The manufacturing method includes the following steps. Firstly, a carrier is provided. Next, a plurality of chips is disposed on the carrier, wherein each chip has an active surface and includes a plurality of pads disposed on the active surface, which is opposite to the carrier. After that, the side-wall of each chip is encapsulated by a molding compound, so that the molding compound and the chips form a chip-redistribution encapsulant, wherein the molding compound has a first surface substantially aligned with the active surface. Afterwards, the carrier is removed, so that the chip-redistribution encapsulant exposes the pads. Subsequently, plasma is applied on the pads and a first surface of the molding compound, so that the first surface becomes rough. Then, a first dielectric layer is formed on the pads and the first surface, wherein the first dielectric layer has a second surface, a third surface and a plurality of first apertures, the second surface is opposite to the third surface and located on the active surface of the chips and the first surface of the molding compound, each first aperture exposes the corresponding pad, the side-wall of each first aperture and the corresponding pad form a bending portion. After that, plasma is applied on the third surface of the first dielectric layer, the side-wall of the first aperture and the top surface of the pads, so that the third surface, the side-wall of each first aperture and the top surface of each pad becomes rough. Subsequently, a patterned conductive layer is formed on a portion of the third surface of the first dielectric layer, the side-wall of each first aperture and the top surface of each pad. Then, a second dielectric layer is formed on the patterned conductive layer and the third surface of the first dielectric layer. After that, a plurality of solder balls is formed on the second dielectric layer. Lastly, the chip-redistribution encapsulant is divided, so as to form a plurality of the semiconductor package.

According to a second aspect of the disclosure, a semiconductor package is provided. The semiconductor package includes a molding compound, a chip, a first dielectric layer, a patterned conductive layer and a second dielectric layer. The chip has an active surface and includes a plurality of pads. The molding compound encapsulates the side-wall of the chip and has a first surface substantially aligned with the active surface. The first dielectric layer has a second surface, a third surface and a plurality of first apertures, wherein the second surface is opposite to the third surface and disposed on the active surface and the first surface, each first aperture expose the corresponding pad, and the side-wall of each first aperture and the corresponding pad form a bending portion. A patterned conductive layer is formed on the third surface, the side-wall of each first aperture and the top surface of each pad, wherein a portion of the patterned conductive layer is continuously located in the bending portion. A second dielectric layer is formed on the patterned conductive layer and the third surface, wherein the first surface, the third surface, the side-wall of each first aperture and the outer surface of the top surface of each pad are rough.

The disclosure will become apparent from the following detailed description of the preferred but non-limiting embodiments. The following description is made with reference to the accompanying drawings.

### BRIEF DESCRIPTION OF THE DRAWINGS

FIG. 1 (Prior Art) shows a partial cross-sectional view of a generally known semiconductor package;

FIG. 2 shows a method flowchart of manufacturing a semiconductor package according to an embodiment of the disclosure; and

FIGS. 3A-3L show the process of manufacturing a semiconductor package according to a first embodiment of the disclosure.

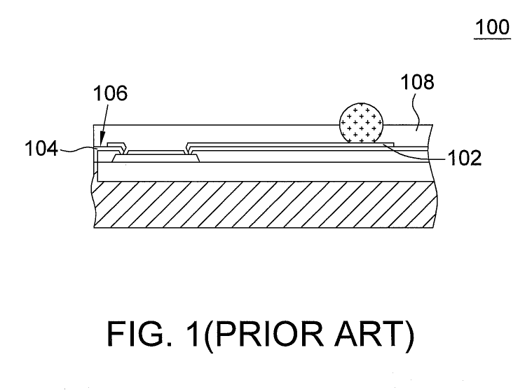

### DETAILED DESCRIPTION

According to the semiconductor package and the manufacturing method thereof disclosed in the disclosure, before a first dielectric layer is formed, plasma surface treatment is applied on a molding compound surface for removing impurities from the molding compound surface and enabling the molding compound surface to form a rough structure, so that the associativity between the first dielectric layer being formed subsquentially and the molding compound surface is increased. After the first dielectric layer is formed, plasma surface treatment can be applied on the surface of the first dielectric layer for removing impurities from the surface of the first dielectric layer and enabling the surface of the first dielectric layer to form a rough structure, so that the associativity between the patterned conductive layer being formed subsquentially and the surface of the first dielectric layer is increased.

A number of embodiments are disclosed below. However, the embodiments and the accompanying drawings are for exemplification purpose only, not for limiting the scope of protection of the disclosure. Also, secondary elements are omitted in the embodiments for highlighting the technical technical features of the disclosure.

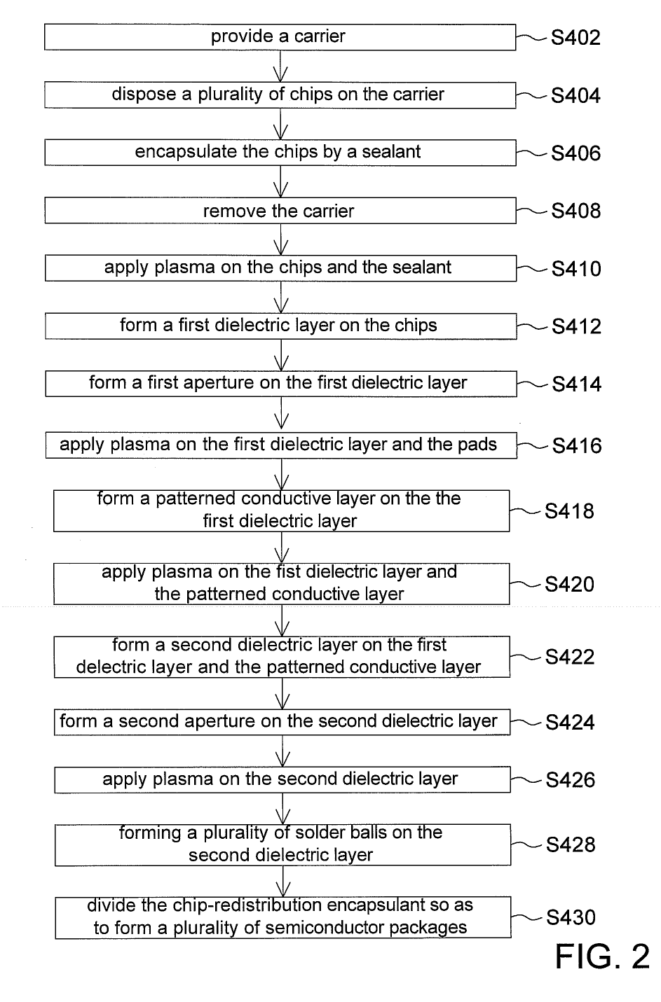

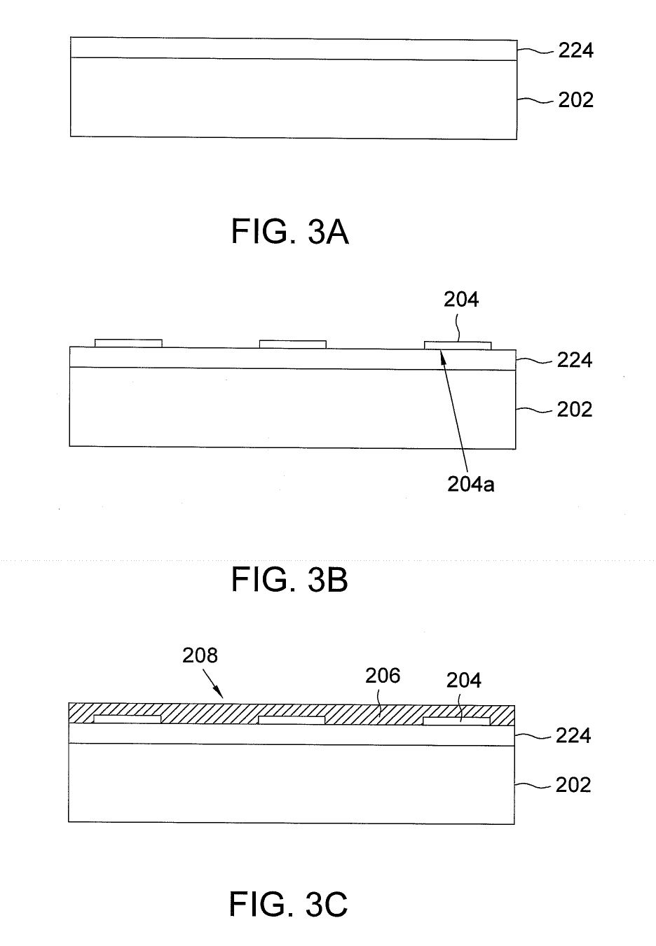

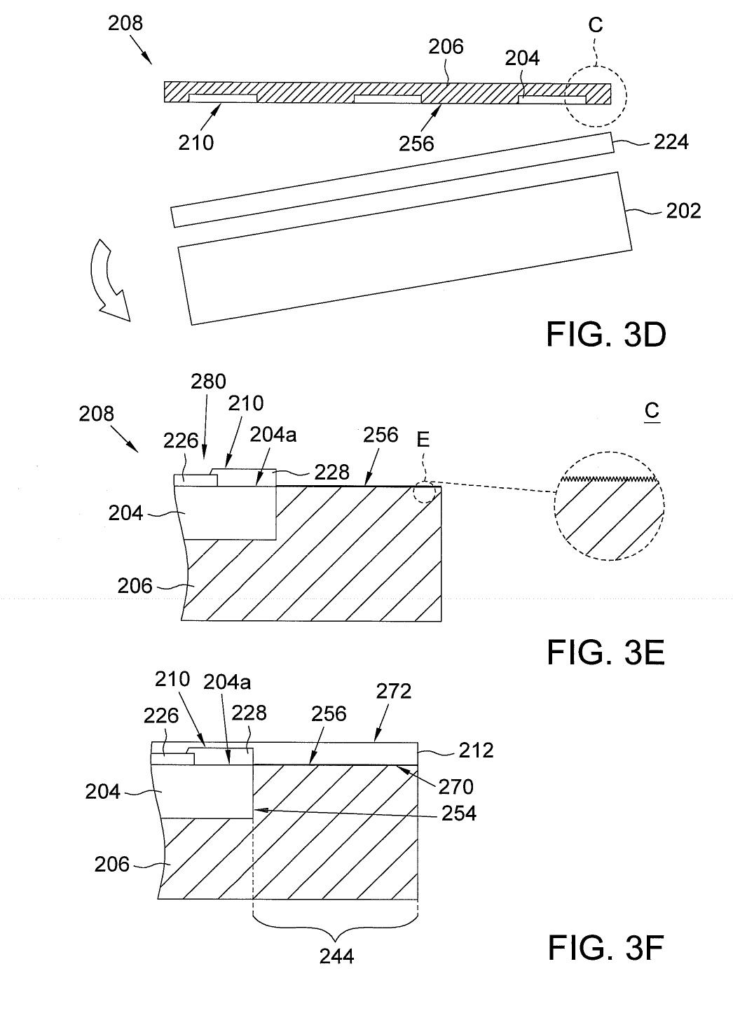

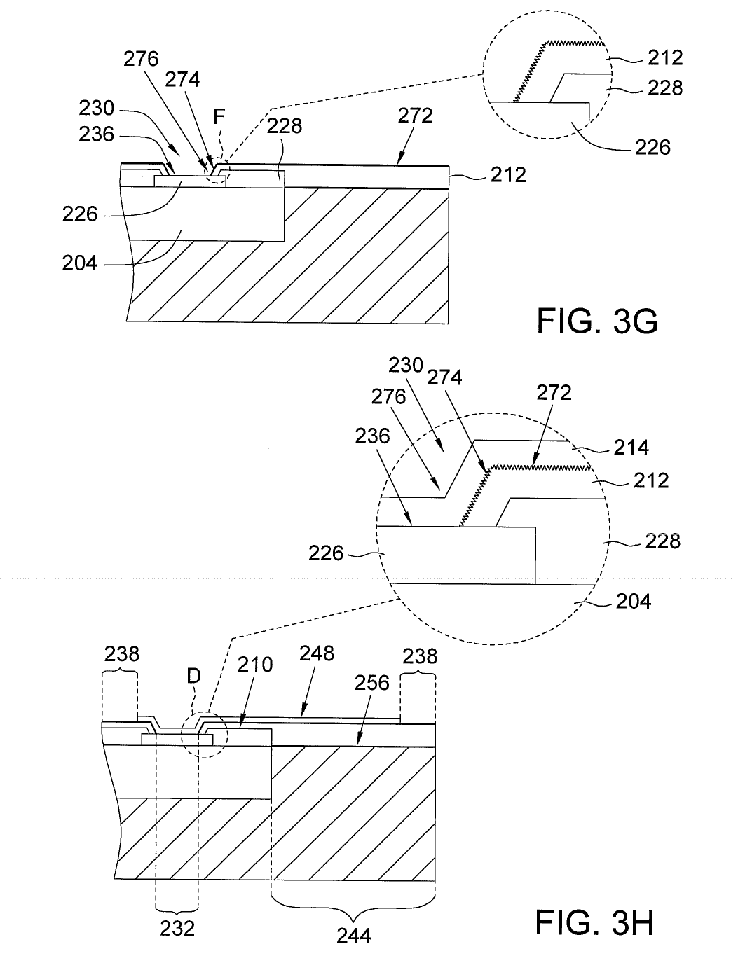

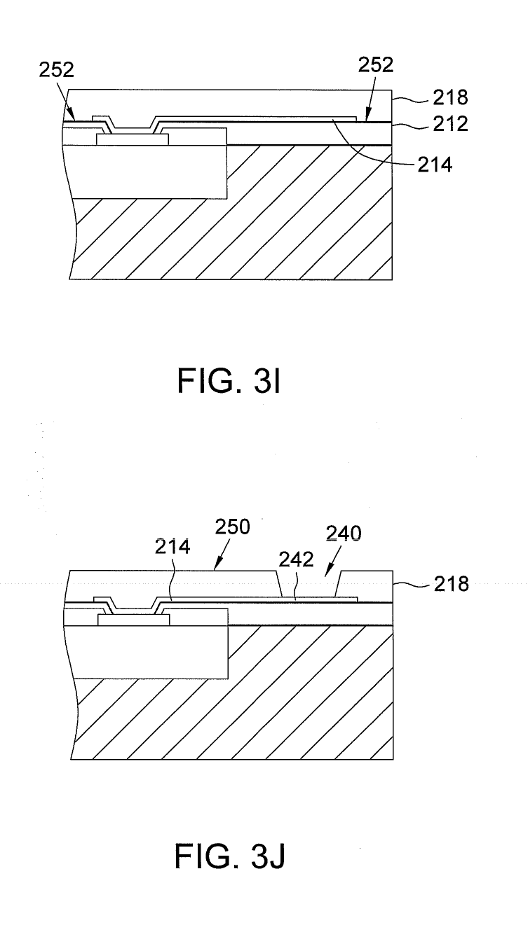

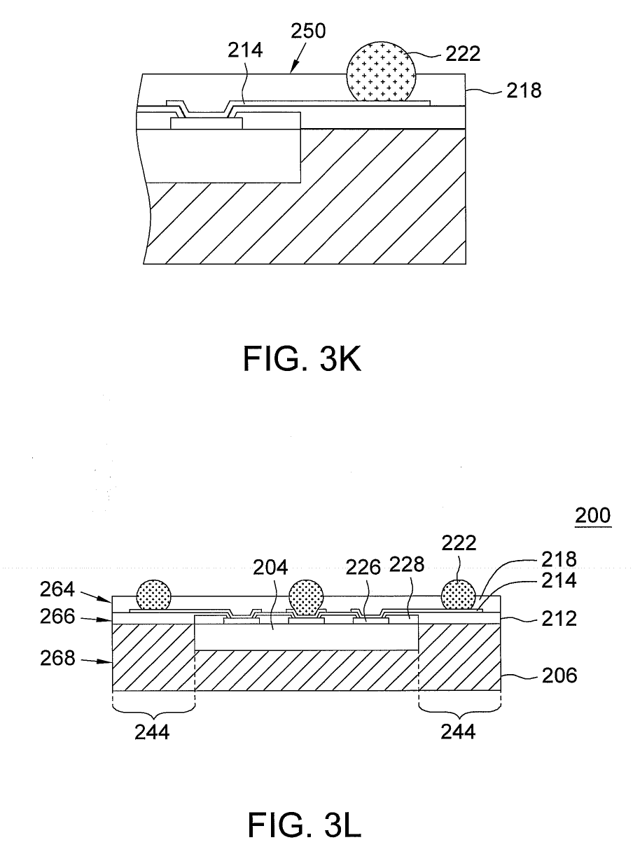

Referring to FIG. 2 and FIGS. 3A-3L at the same time. FIG. 2 shows a method flowchart of manufacturing a semiconductor package according to an embodiment of the disclosure. FIGS. 3A-3L show the process of manufacturing a semiconductor package according to a first embodiment of the disclosure.

Firstly, the method begins at step S402 as indicated in FIG. 3A, a carrier 202 including an adhesive film 224 is provided.

Next, the method proceeds to step S404 as indicated in FIG. 3B, a plurality of chips 204 are disposed on the adhesive film 224 of the carrier 202, wherein an active surface 204a of each chip 204 faces the carrier 202.

Then, the method proceeds to step S406 as indicated in FIG. 3C, the chips 204 are encapsulated by a molding compound 206, so that the molding compound 206 and the chips 204 form a chip-redistribution encapsulant 208.

After that, the method proceeds to step S408 as indicated in FIG. 3D, the carrier 202 and the adhesive film 224 are removed, so that the chip-redistribution encapsulant 208 exposes a first surface 256 of the molding compound 206, wherein the chip surface 210 and the first surface 256 face downwards in FIG. 3D. However, the chip surface 210 and the first surface 256 can face upwards by way of inverting the chip-redistribution encapsulant 208 as indicated in FIG. 3E.

FIG. 3E shows an enlargement of the region C of FIG. 3D. Each chip 204 includes a plurality of pads 226, and the chip-redistribution encapsulant 208 includes a protective layer 228. The protective layer 228, such as a nitride layer or an oxide layer, has a protective layer aperture 280 for exposing the pads 226. In FIG. 3E, the number of pads 226 is exemplified by one.

Afterwards, the method proceeds to step S410, plasma is applied on the pad 226 and the first surface 256 of the molding compound 206. Through plasma surface treatment, impurities such as oxides are removed from the first surface 256 of the molding compound 206, hence increasing the associativity between the chip surface 210, the pad 226, the first surface 256 and the structure being formed subsequently such as a first dielectric layer 212 (illustrated in FIG. 3F).

Through plasma surface treatment, the first surface 256, being hit by plasma particles, has many nanoscale recesses formed thereon. The first surface 256 of the present embodiment of the disclosure is rough as indicated in an enlargement of the region E of FIG. 3E, further increasing the associativity between the first surface 256 and the structure being formed subsequently, that is, the first dielectric layer 212 (illustrated in FIG. 3F).

Furthermore, the molding compound 206 and the first dielectric layer 212 are made from different materials. By making the surface of the molding compound 206 rough, the associativity between the molding compound 206 and the first dielectric layer 212 is increased.

Then, the method proceeds to step S412 as indicated in FIG. 3F, the first dielectric layer 212 is formed on the chip surface 210, the first surface 256 and the pad 226, wherein the first dielectric layer 212 is made from polymer for example. Besides, the first dielectric layer 212 has a second surface 270 and a third surface 272, wherein the second surface 270 is opposite to the third surface 272 and disposed on the chip 204 and the first surface 256. That is, the second surface 270 covers the protective layer 228, the pad 226 and a portion of the first surface 256.

On the part of the semiconductor package of the present embodiment of the disclosure, a portion of the first dielectric layer 212 is overlapped with a portion 244 of the molding compound, wherein the portion 244 of the molding compound 206 is formed on the side-wall 254 of the chip 204, and the first surface 256 belongs to the surface of the portion 244 of the molding compound 206 and is substantially aligned with the active surface 204a.

Then, the method proceeds to step S414 as indicated in FIG. 3G, a first aperture 230 is formed on the first dielectric layer 212, so that the first aperture 230 exposes the pad 226, wherein the side-wall 274 of the first aperture 230 and the pad 226 form a bending portion 276.

Afterwards, the method proceeds to step S416, plasma is applied on the third surface 272 (illustrated in FIG. 3G) of the first dielectric layer 212, the side-wall 274 (illustrated in FIG. 3G) of the first aperture 230 and the top surface 236 (illustrated in FIG. 3G) of the pad 226 for removing impurities such as oxides from the third surface 272 of the first dielectric layer 212, the side-wall 274 and the top surface 236, hence increasing the associativity between the patterned conductive layer being 214 (illustrated in FIG. 3H) formed subsequently and the bending portion 276 as well as the associativity between the patterned conductive layer 214 and the first dielectric layer 212.

Through plasma surface treatment, the third surface 272 and the side-wall 274, being hit by plasma particles, have many nanoscale recesses formed thereon and become a rough surface as indicated in an enlargement of the region F of FIG. 3G. Both the third surface 272 and the bending portion 276 of the present embodiment of the disclosure are rough surface, further increasing the associativity between the third surface 272, the bending portion 276 and the structure being formed subsequently, that is, the patterned conductive layer 214. Furthermore, the first dielectric layer 212 and the patterned conductive layer 214 are made from different materials. By making the surface of the first dielectric layer 212 rough, the associativity between the first dielectric layer 212 and the patterned conductive layer 214 is increased.

Then, the method proceeds to step S418 as indicated in FIG. 3H, the patterned conductive layer 214 such as a redistribution layer (RDL) is formed on the third surface 272 of the first dielectric layer 212, the side-wall 274 of the first aperture 230 and the top surface 236 of the pad 226 by way of sputtering. The patterned conductive layer 214 connects and covers the portion 232 of the pad 226 exposed from the first aperture 230, wherein a portion of the patterned conductive layer 214 is extended and overlapped with the portion 244 of the molding compound.

Besides, before the first dielectric layer 212 is formed, impurities are removed form the pad 226 during the plasma manufacturing process of step S410, so that an indented unfilled corner (not illustrated) will not occur during the formation of the first dielectric layer 212 as indicated in an enlargement of the region D of FIG. 3H. Therefore, a portion of the patterned conductive layer 214 formed on the bending portion 276 is continual.

Next, the method proceeds to step S420, plasma is applied on another portion of the third surface 238 (illustrated in FIG. 3H) of the first dielectric layer 212 and the patterned conductive layer 214 for removing impurities from the third surface 238 of another part of the first dielectric layer 212 and from the surface 248 (illustrated in FIG. 3H) of the patterned conductive layer 214, hence increasing the associativity between the another part of the third surface 238 and the second dielectric layer 218 (illustrated in FIG. 3I) being formed subsequently as well as the associativity between the patterned conductive layer 214 and the second dielectric layer 218 being formed subsequently. Wherein, the third surface 238 is a portion of the third surface 272, the third surface 238 is the surface by which the third surface 272 contacts the patterned conductive layer 214.

Then, the method proceeds to step S422 as indicated in FIG. 3I, the second dielectric layer 218 is formed on the patterned conductive layer 214 and another part of the third surface 238 (illustrated in FIG. 3H) of the first dielectric layer 212, wherein the second dielectric layer 218 is made from polymer for example.

During the plasma manufacturing process of step S420, the residual metal atoms, which are generated during the execution of step S418 but are left on the third surface 238 and not connected to the patterned conductive layer 214, are effectively removed. Thus, the second dielectric layer 218 can be completely deposited on a clean third surface 238 (illustrated in FIG. 3H) and will not generate the conductive layer at the border surface 252 between the third surface 238 and the second dielectric layer 218. Thus, the manufacturing method of the present embodiment of the disclosure effectively avoids the problem of residual current leakage.

Then, the method proceeds to step S424 as indicated in FIG. 3J, a second aperture 240 is formed on the second dielectric layer 218, so that the second aperture 240 exposes a portion 242 of the patterned conductive layer 214.

Besides, after step S424, solder ball pads (not illustrated) can be formed on a portion 242 of the patterned conductive layer 214 to increase the associativity and conductive stability between the solder balls being formed subsequently and the patterned conductive layer 214.

After that, the method proceeds to step S426, plasma is applied on the second dielectric layer 218 for removing impurities from the surface 250 (illustrated in FIG. 3J) of the second dielectric layer 218 and from a portion 242 (illustrated in FIG. 3J) of the patterned conductive layer 214 so as to increase the associativity between the patterned conductive layer 214 the solder balls being formed subsequently.

Afterwards, the method proceeds to step S428 as indicated in FIG. 3K, a solder ball 222 is formed on the second dielectric layer 218 according to the position of the second aperture 240 (illustrated in FIG. 3J), so that the solder ball 222 is electrically connected to the patterned conductive layer 214.

Then, the method proceeds to step S430 as indicated in FIG. 3L, the chip-redistribution encapsulant 208 with the abovementioned structure is divided into a plurality of semiconductor packages 200 according to the position of the chip 204. The abovementioned structure is the structure formed in steps S412-S428. As the cutting path passes through the overlapping of the first dielectric layer 212, the second dielectric layer 218 and the molding compound 206, on the part of the semiconductor package 200 being cut, the side surface 264 of the first dielectric layer 212, the side surface 266 of the second dielectric layer 218 and the side surface 268 of the molding compound 206 are substantially aligned with one another.

On the semiconductor package 200 of the present embodiment of the disclosure, a portion of the patterned conductive layer 214 and a portion of solder balls 222 can be extended and overlapped with the portion 244 of the molding compound 206, so that the number of I/O contacts of the semiconductor package 200 is increased.

The semiconductor package and the manufacturing method thereof disclosed in the above embodiments of the disclosure have many features exemplified below.

(1) Before the first dielectric layer is formed, plasma is applied on the pad for removing impurities from the pad, so that the patterned conductive layer is formed subsequently.

(2) Before the first dielectric layer is formed, plasma is applied on the molding compound, not only removing impurities from the molding compound but also making the molding compound a rough surface and tightly coupled with the first dielectric layer being formed subsequently to prevent the acid gases in the air from invading the structure.

(3) After the first dielectric layer is formed but before the patterned conductive layer is formed, plasma is applied on the first dielectric layer, not only removing impurities from the first dielectric layer but also making the first dielectric layer a rough surface and tightly coupled with the patterned conductive layer being formed subsequently to prevent the acid gases in the air from invading the structure.

(4) After the first dielectric layer and the patterned conductive layer are formed, plasma is applied on the residual metal atoms left on the first dielectric layer, so that the second dielectric layer being formed subsequently can be completely deposited on the first dielectric layer. The Conductive layer will not be generated between the first dielectric layer and the second dielectric layer, the problem of residual current leakage will not occur.

While the disclosure has been described by way of example and in terms of an embodiment, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package, comprising:
a chip having an active surface and comprising a plurality of pads;
a molding compound used for encapsulating the side-wall of the chips, wherein the molding compound has a first surface substantially aligned with the active surface;
a first dielectric layer having a second surface, a third surface and a plurality of first apertures, wherein the second surface is opposite to the third surface and disposed on the active surface of the chips and the first surface of the molding compound, each of the first apertures exposes the corresponding pad, and a side-wall of each of the first apertures and the corresponding pad form a bending portion;
a patterned conductive layer formed on the third surface, the side-wall of each of the first apertures and a top surface of each pad, wherein a portion of the patterned conductive layer is continuously disposed on the bending portion; and
a second dielectric layer formed on the patterned conductive layer and the third surface;
wherein, the first surface, the third surface, the side-wall of each of the first apertures and the top surface of each of the pads are a rough surface.

2. The semiconductor package according to claim 1, wherein the rough surface is a surface formed after plasma surface treatment.

3. The semiconductor package according to claim 2, wherein the rough surface has a plurality of recesses.

4. The semiconductor package according to claim 3, wherein the dimensions of the recesses are nanoscale.

5. The semiconductor package according to claim 1, wherein the chip further comprises:
a protective layer formed on the active surface of the chip, wherein the protective layer has a plurality of protective layer apertures exposing the pads.

6. The semiconductor package according to claim 5, wherein the protective layer and a portion of each of the pads are covered by the second surface of the first dielectric layer.

7. The semiconductor package according to claim 1, wherein the second dielectric layer further comprises:
a plurality of second apertures exposing a portion of the patterned conductive layer; and
a plurality of solder balls formed on the second apertures so that the solder balls are electrically connected to the patterned conductive layer.

8. The semiconductor package according to claim 1, wherein the side surface of the first dielectric layer, the side surface of the second dielectric layer and the side surface of the molding compound are substantially aligned with one another.

9. The semiconductor package according to claim 1, wherein the patterned conductive layer is a redistribution layer (RDL).

10. A manufacturing method of a semiconductor package, comprising:
providing a carrier;
disposing a plurality of chips on the carrier, wherein each of the chips has an active surface and comprises a plurality of pads disposed on the active surface, wherein the active surface faces the carrier;
encapsulating the side-wall of the chips by a molding compound, so that the molding compound and the chips form a chip-redistribution encapsulant, wherein the molding compound has a first surface substantially aligned with the active surfaces;
removing the carrier, so that the chip-redistribution encapsulant exposes the pads;
applying plasma on the pads and the first surface of the molding compound, so that the first surface becomes rough;
forming a first dielectric layer on the pads and the first surface, wherein the first dielectric layer has a second surface, a third surface opposite to the second surface and a plurality of first apertures, and the second surface is located on each of the active surfaces and the first surface of the molding compound, each of the first apertures exposes the corresponding pad, and a side-wall of each of the first apertures and the corresponding pad form a bending portion;
applying plasma on the third surface of the first dielectric layer, the side-wall of each of the first apertures and a top surface of each of the pads, so that the third surface, the side-wall of each of the first apertures and the top surface of each of the pads become rough;
forming a patterned conductive layer on the third surface, the side-wall of each of the first apertures and the top surface of each of the pads, wherein a portion of the patterned conductive layer is continuously disposed on the bending portion;
forming a second dielectric layer on the patterned conductive layer and the third surface of the first dielectric layer;
forming a plurality of solder balls on the second dielectric layer; and
dividing the chip-redistribution encapsulant so as to form a plurality of semiconductor packages.

11. The manufacturing method according to claim 10, further comprising:
providing a adhesive film on the carrier; and
the step of disposing the chips on the carrier comprises:
disposing the chips on the adhesive film, wherein the active surfaces faces the adhesive film.

12. The manufacturing method according to claim 10, wherein after the step of forming the patterned conductive layer and before the step of forming the second dielectric layer, the method further comprises:
applying plasma on the first dielectric layer and the patterned conductive layer.

13. The manufacturing method according to claim 10, wherein in the step of forming the patterned conductive layer, the patterned conductive layer connects and covers a portion of the pads exposed from the first apertures.

14. The manufacturing method according to claim 10, wherein after the step of forming the second dielectric layer the step, the manufacturing method further comprises:
applying plasma on the second dielectric layer.

15. The manufacturing method according to claim 10, wherein the step of forming the patterned conductive layer is achieved by way of sputtering.

16. The manufacturing method according to claim 10, wherein after the step of forming the second dielectric layer, the manufacturing method further comprises:
forming a plurality of second apertures on the second dielectric layer, so that the second apertures respectively expose a portion of the patterned conductive layer.

17. The manufacturing method according to claim 16, wherein the step of forming the solder balls on the second dielectric layer comprises:
forming the solder balls in the second apertures according to the positions of the second apertures, so that the solder balls are electrically connected to the patterned conductive layer.

18. The manufacturing method according to claim 10, wherein the chip further comprises:
a protective layer having a plurality of protective layer apertures exposing the pads.

19. The manufacturing method according to claim 18, wherein the protective layer is a nitride layer or an oxide layer.

20. The manufacturing method according to claim 10, wherein the step of dividing the chip-redistribution encapsulant comprises:
dividing the chip-redistribution encapsulant along a cutting path, wherein the cutting path passes through the overlapping between the first dielectric layer, the second dielectric layer and the molding compound, so that on the part of the divided semiconductor package, the side surface of the first dielectric layer, the side surface of the second dielectric layer and the side surface of the molding compound are substantially aligned with one another.
